(19) United States
(12) Patent Application Publication
(10) Pub. No.: US 2011/0254063 A1
(43) Pub. Date: Oct. 20, 2011

(54) SEMICONDUCTOR DEVICE STRUCTURE AND METHOD FOR MANUFACTURING THE SAME

(75) Inventors: Shijie Chen, Beijing (CN); Wenwu Wang, Beijing (CN); Xiaolei Wang, Beijing (CN); Kai Han, Beijing (CN)

(73) Assignee: INSTITUTE OF MICROELECTRONICS, CHINESE ACADEMY OF SCIENCES, Beijing (CN)

(21) Appl. No.: 13/063,693

(22) PCT Filed: Sep. 27, 2010
(86) PCT No.: PCT/CN10/77339

§ 371 Date: Mar. 11, 2011

(30) Foreign Application Priority Data
Apr. 20, 2010 (CN) 201010153756.1

(51) Int. Cl. H01L 29/78; H01L 21/321; B82Y 99/00; B82Y 40/00

(52) U.S. Cl. 257/288; 438/592; 977/755; 257/E29.255; 257/E21.19

(57) ABSTRACT

The present invention provides a MOS device, which comprises: a substrate; an interface layer thin film formed on the substrate; a high k gate dielectric layer formed on the interface layer thin film; and a metal gate formed on the high k gate dielectric layer. The metal gate comprises, upwardly in order, a metal gate work function layer, an oxygen absorption element barrier layer, a metal gate oxygen absorbing layer, a metal gate barrier layer and a polysilicon layer. A metal gate oxygen absorbing layer is introduced into the metal gate for the purpose of preventing the outside oxygen from coming into the interface layer and absorbing the oxygen in the interface layer during a annealing process, such that the interface layer is reduced to be thinner and the EOT of MOS devices are effectively reduced; meanwhile, by adding an oxygen absorption element barrier layer, the “oxygen absorption element” is prevented from diffusing into the high k gate dielectric layer and giving rise to unfavorable impact thereon; in this way, the high k/metal gate system can be more easily integrated, and the performance of the device can be further improved accordingly.

### FIELD OF THE INVENTION

The present invention relates to design and fabrication of semiconductor, and particularly, to a semiconductor structure and a method for manufacturing the same.

### BACKGROUND OF THE INVENTION

In the past decades which witnessed the development of the microelectronics technology, logic chip manufacturers always made use of SiO₂ as gate dielectric and heavily doped polysilicon as the gate electrode when manufacturing MOS devices. However, with continued scaling of the feature size, the SiO₂ gate dielectric within MOS transistor almost come to its limit. For example, in the 65 nm process, the thickness of the SiO₂ gate dielectric is lowered to 1.2 nm, which namely is equivalent of the thickness of about 5 silicon atom layers. With further scaling, the leakage current and power consumption may increase dramatically. Meanwhile, the problems such as diffusion of doped boron atoms, polysilicon depletion effect and overly high gate resistance arising from polysilicon electrode will be increasingly aggravated. Therefore, as for the technology generations at 32 nm and below, research and development of new materials, new processes and new device structures are earnestly needed for tackling the issues such as the dramatically increased leakage current and power consumption.

In order to reduce the leakage current and power consumption, a prior art provides now such an improved technique that applies a “high k/metal gate” structure. To date, the major semiconductor companies all over the world have already been devoted to the research and development of “high k/metal gate” of the technology generation at 32 nm and below. Intel has disclosed that once the high k gate dielectric material is applied, the leakage current of the device may reduce to a tenth of its original. However, the high-temperature annealing process has to be applied in the high k/metal gate process, which, as a result, would make the SiO₂ interface layer become thicker during the annealing process. On the other hand, the CMOS devices at the 45 nm node and below need gate dielectrics with EOT (Equivalent Oxide Thickness) no thicker than 1 nm to improve the gate control of the channel, which the relatively thick SiO₂ interface layer is impossible to fulfill. Particularly in the 32 nm and 22 nm technologies, the EOT of gate dielectrics are required as far as to be 0.7 nm or even smaller than 0.5 nm, whereas the SiO₂ interface layer in the conventional high k/metal gate process would become 0.5-0.7 nm thick. Accordingly, how to reduce EOT, particularly to reduce EOT attributed by the SiO₂ interface layer, becomes a critical challenge for the new generation of high k/metal gate technology.

we find during our research that, during a high-temperature annealing process, although the oxygen in the peripheral atmosphere cannot come into the gate dielectric structure, some metal thin films or other unsaturated oxidized dielectric thin films may “absorb” oxygen in the interface layer (such as SiO₂) between the high k gate dielectric and the semiconductor substrate, since the Gibbs Free Energy Change of these metals or the unsaturated oxidized dielectrics is far greater than that of the semiconductor substrate (e.g. Si); and it means that the oxides of these metals or the saturated oxides of these unsaturated oxidized dielectrics are more stable than the oxide(s) of the semiconductor substrate and much easier to form. In short, during a high-temperature thermal process, the oxygen within the interface layer is driven to form metallic oxide(s) with “such a metal or unsaturated oxidized dielectric that absorbs oxygen”, which thus reduces the thickness of the interface layer, and even makes it depleted.

A typical oxygen absorption process is to insert an oxygen absorption metal layer into the high k gate dielectrics, which then absorbs the oxygen in the interface layer by means of high-temperature annealing. Nonetheless, such a “direct oxygen absorption process” that introduces “an oxygen absorption metal” into high k gate dielectric is still subject to some shortcomings, for instance, such kind of “oxygen absorption metal” would directly result in the change of the high k gate dielectric, and give rise to other unfavorable impacts on the performance of MOS devices.

### SUMMARY OF THE INVENTION

The present invention aims to at least solve one of the abovementioned technical defects, and particularly, to bring forth effects of reducing EOT of the devices without negative impact on the high k dielectrics layer by introducing “an indirect oxygen absorption process”.

To fulfill the above mentioned objects, on one hand, the present invention provides a gate structure of MOS device, which comprises: a substrate; an interface layer thin film formed on the substrate; a high k gate dielectric layer formed on the interface layer thin film; and a metal gate formed on the high k gate dielectric layer. The metal gate comprises, upwardly in order, a metal gate work function layer, an oxygen absorption element barrier layer, a metal gate oxygen absorbing layer, a metal gate barrier layer and a polysilicon layer.

On the other hand, the present invention provides a MOS device, which comprises a gate structure as described above.

In another aspect, the present invention further provides a method for forming the gate structure of the abovementioned MOS device, which comprises following steps: providing a substrate; forming an interface layer thin film on the substrate; forming a high k gate dielectric layer on the interface layer thin film; forming a metal gate work function layer on the high k gate dielectric layer; forming an oxygen absorption element barrier layer on the metal gate work function layer; forming a metal gate oxygen absorbing layer on the oxygen absorption element barrier layer; forming a metal gate barrier layer on the metal gate oxygen absorbing layer; forming a polysilicon layer on the metal gate barrier layer; and forming the complete gate structure by performing a rapid thermal annealing process.

In the present invention, a metal gate oxygen absorbing layer is introduced into the metal gate for the purpose of preventing the outside oxygen from coming into the interface layer and absorbing the oxygen in the interface layer during the annealing process, such that the interface layer is reduced to be thinner and the EOT of MOS devices are effectively reduced. Meanwhile, ascribing to adding an oxygen absorption element barrier layer, the “oxygen absorption element” is prevented from diffusing into the high k gate dielectric layer and giving rise to unfavorable impact thereon. In this way, the high k/metal gate system can be more easily integrated, and the performance of the device can be further improved accordingly.

The additional aspects and advantages of the present invention will be described in part in the following text, and other part(s) should become obvious with following in-depth description or can be comprehended according to the practice of the present invention.

### BRIEF DESCRIPTION OF THE DRAWINGS

The abovementioned and/or additional aspects and advantages of the present invention will become more obvious and comprehensible on account of the disclosure of the embodiments with reference to the drawings, which of course are illustrative and thus are not drawn to scale. Wherein:

FIG. 1 illustrates the schematic diagram of the gate structure of the MOS device according to the embodiment of the present invention.

FIGS. 2-8 illustrate the schematic diagrams of the intermediate steps for forming the gate structure of the MOS device according to the embodiment of the present invention.

### DETAILED DESCRIPTION OF THE INVENTION

Described below in detail are the embodiments of the present invention, whose exemplary models also are illustrated in the drawings; wherein the same or similar numbers throughout the drawings denote the same or similar elements or elements have the same or similar functions. The embodiments described below with reference to the drawings are merely illustrative, and are provided for explaining the present invention only, thus should not be interpreted as a limit to the present invention.

The following disclosure provides a plurality of different embodiments or examples to achieve different structures of the present invention. To simplify the disclosure of the present invention, description of the components and arrangements of specific examples is given below. Of course, they are only illustrative and not limiting the present invention. Moreover, in the present invention, reference numbers and/or letters may be repeated in different embodiments. Such repetition is for the purposes of simplification and clearness, and does not denote the relationship between respective embodiments and/or arrangements being discussed. In addition, the present invention provides various examples for specific process and materials. However, it is obvious for a person of ordinary skill in the art that other process and/or materials may alternatively be utilized. Furthermore, the following structure in which a first object is “on” a second object may include an embodiment in which the first object and the second object are formed to be in direct contact with each other, and may also include an embodiment in which another object is formed between the first object and the second object such that the first and second objects might not be in direct contact with each other.

The present invention is intended to prevent the outside oxygen from entering into the interface layer and also to absorb the oxygen in the interface layer during the annealing process by means of introducing a metal gate oxygen absorption layer into the metal gate, so as to reduce the EOT of MOS devices.

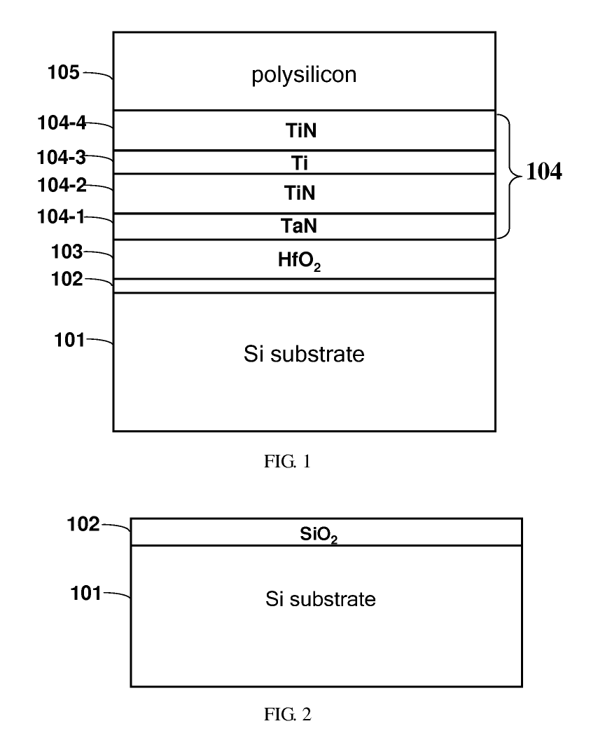

FIG. 1 shows the schematic diagram of the gate structure of the MOS device provided in the embodiment of the present invention. This structure comprises upwards in order: a semiconductor substrate 101, an interface layer thin film 102, an high k gate dielectric layer 103, a metal gate 104 and a polysilicon layer 105, wherein, the metal gate 104 comprises a multi-layer material layer which, specifically, comprises a metal gate work function layer 104-1, an oxygen absorption element barrier layer 104-2, a metal gate oxygen absorbing layer 104-3 and the metal gate barrier layer 104-4. The element(s) contained within the metal gate oxygen absorbing layer 104-3 must be capable of absorbing oxygen from the interface layer during a thermal processing, while the oxygen absorption element barrier layer 104-2 is added for the purpose of preventing “oxygen absorption element(s)” from diffusing into the high k gate dielectric layer 103 and thereby causing unfavorable impact thereon.

In order to reach a clearer comprehension of the gate structure of the semiconductor device proposed, the present invention further provides an embodiment of the method for forming the semiconductor structure. It should be noted that those skilled in the art may, according to the semiconductor structure, choose various processes for fabrication, such as product lines of different types, different process flows and the like. However, whenever a semiconductor structure fabricated following theses processes adopts a structure substantially similar to said structure of the present invention and even achieves the substantially identical effect, it should be included within the protection scope of the present invention. In order to draw a clearer comprehension of the present invention, the method(s) and process(es) for forming the structure thereof are described in detail, but it is noteworthy that the steps given below are only illustrative, rather than limiting the present invention; and those skilled in the art also may make it by means of other processes.

FIGS. 2 to 8 illustrate the schematic diagrams of the intermediate steps for forming the gate structure of the MOS device according to the embodiment of the present invention, wherein the method comprises following steps:

Step 1: providing a semiconductor substrate 101. In this embodiment, the substrate 101 is exemplified as Si, whereas in practice the substrate may comprise any semiconductor substrate materials as appropriate, which may be, but not limited to, Si, Ge, GeSi, GaAs, InP, GaInAs, SiC, SOI (silicon on insulator) or any III/V-group compound semiconductors. According to the design specifications known in the prior art (for example, a p-type substrate or an n-type substrate), the substrate 101 may be of various doping configurations. Additionally, the substrate 101 may optionally include an epitaxial layer, and may be under stress to enhance performance.

Step 2: growing an interface layer thin film 102 on the substrate 101 with a thickness of about 0.2-0.8 nm, as shown in FIG. 2. In the embodiment thereof, the interface layer thin film 102 is a SiO₂ thin film.

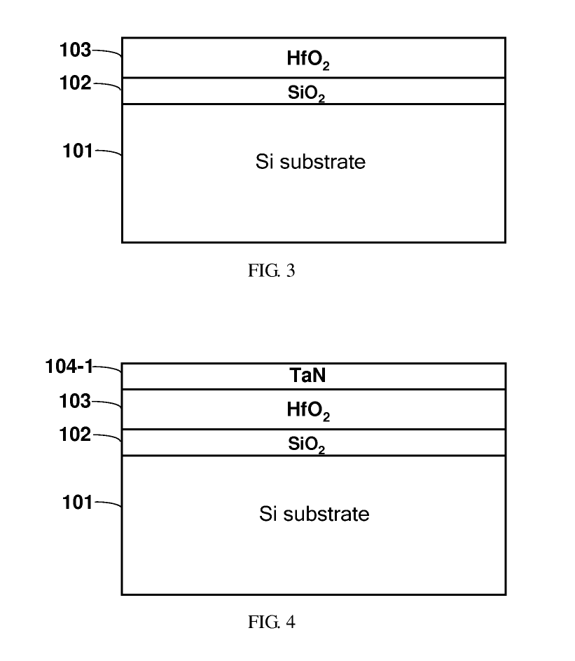

Step 3: growing a high k gate dielectric layer 103 on the interface layer thin film 102 with a thickness of about 1-3 nm, as shown in FIG. 3. The high k dielectric layer may include HfO₂, HfSiO, HfSiON, HfTaO, HfTiO, HfZrO, and/or other appropriate materials and any combination thereof. The high k gate dielectric layer 103 may be formed by such techniques as Chemical Vapor Deposition (CVD) or Atomic Layer Deposition (ALD). In the embodiment thereof, the high k dielectric layer 103 is an HfO₂ thin film and formed by ALD.

Step 4: depositing a metal gate work function layer 104-1 on the high k dielectric thin film 103 with a thickness of about 5-30 nm, as shown in FIG. 4. The metal gate work function layer 104-1 may include TaC, HfC, TiC, TiN, TiSiN, TaTbN, TaErN, TaYbN, TaSiN, HfSiN, RuTaₓ, NiTaₓ, TaN, MoSiN, MoNₓ, TiCN, TaAlC, TiAlN, PtSiₓ, NiSiₓ, Pt, Ru, Ir, Mo, HfRuₓ, RuOₓ or any combination thereof. In the embodiment thereof, the metal gate work function layer 104-1 is a TaN thin film.

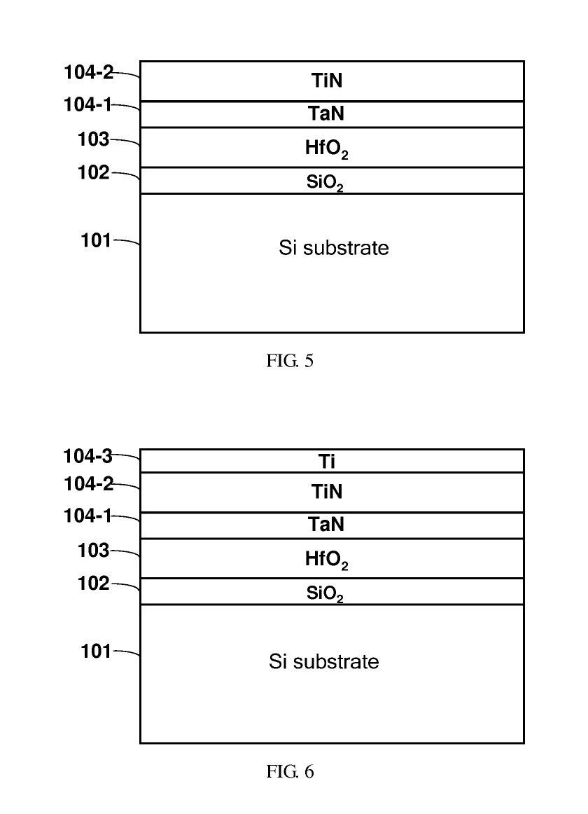

Step 5: depositing an oxygen absorption element barrier layer 104-2 on the metal gate work function layer 104-1 with a thickness of about 2-15 nm, as shown in FIG. 5. The oxygen absorption element barrier layer 104-2 may be formed of TiN, TaN, HfN, TiSiN, TaSiN, HfSiN or any combination thereof. In the embodiment thereof, the oxygen absorption element barrier layer 104-2 is TiN.

Step 6: depositing a metal gate oxygen absorbing layer 104-3 on the oxygen absorption element barrier layer 104-2 with a thickness of about 1-10 nm, as shown in FIG. 6. The element(s) contained in the metal gate oxygen absorbing layer 104-3 must be capable of absorbing oxygen from the interface layer during a thermal process, and may include Ti, Hf, Al, Be, Mg or any combination thereof. In the embodiment thereof, the metal gate oxygen absorbing layer is Ti.

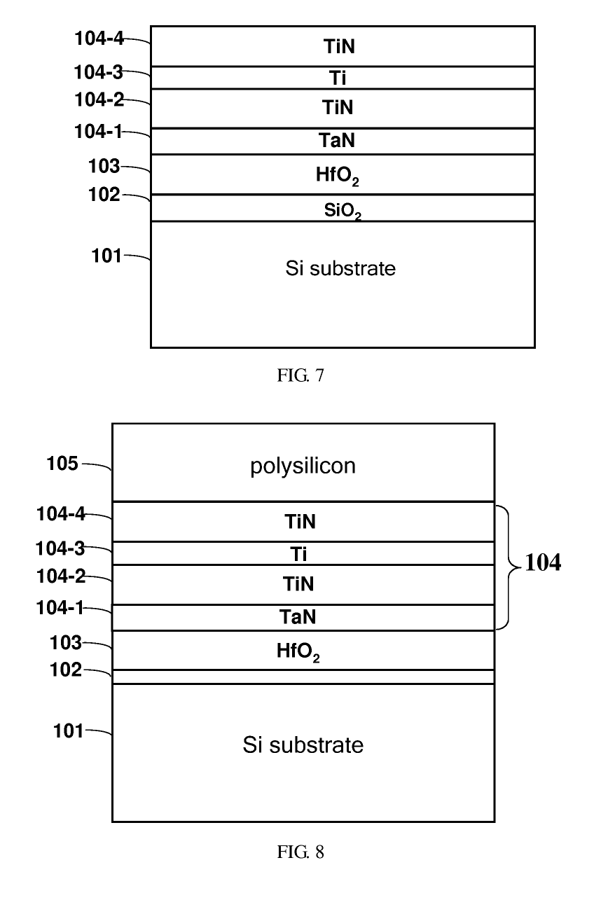

Step 7: depositing a metal gate barrier layer 104-4 on the metal gate oxygen absorbing layer 104-3 with a thickness of 2-15 nm, as shown in FIG. 7. The metal gate barrier layer 104-4 may be formed of TiN, TaN, HfN, TiSiN, TaSiN, HfSiN or any combination thereof. The metal gate barrier layer 104-4 is a TiN thin film in the embodiment of the present invention.

It should be noted that the depositions in steps 4 to 7 may be performed by conventional deposition processes, such as sputtering, PLD, MOCVD, ALD, PEALD or other appropriate methods.

Step 8: depositing a polysilicon layer 105 on the metal gate barrier layer 104-3 with a thickness of about 30-70 nm, as shown in FIG. 8.

Step 9: performing rapid thermal annealing to the gate structure at a temperature around 300-1000° C. for about 5 to 300 seconds. The processed structure is shown in FIG. 1, and its SiO₂ interface layer is about 0-0.5 nm thick.

The present invention proposes a solution of introducing a metal gate oxygen absorbing layer into the metal gate to prevent the outside oxygen from coming into the interface layer in an annealing process, so as to prevent the SiO₂ interface layer from becoming thicker. Besides, on account of the oxygen absorption technique, the SiO₂ interface layer, which is originally as thick as 0.2-0.8 nm, would become no thicker than 0.5 nm during the annealing process or even be completely depleted, so that the EOT of the devices can be effectively lowered down. Additionally, by adding an oxygen absorption element barrier layer, the “oxygen absorption element” is prevented from diffusing into the high k gate dielectric layer and giving rise to unfavorable impact thereon. In this way, the high k/metal gate system can to be more easily integrated, and the performance of the device can be further improved accordingly.

Although the embodiments of the present invention have already been illustrated and described, it is readily apparent to those having ordinary skill in the art that various alternations, amendments, substitutions and modifications may be made to the embodiments without departing from the spirit and principles of the present invention, and the scope of the present invention is defined by the appended claims and their counterparts.

1. A gate structure of a MOS device, comprising:
a substrate;
an interface layer thin film formed on the substrate;
a high k gate dielectric layer formed on the interface layer thin film; and
a metal gate formed on the high k gate dielectric layer, which comprises upwardly in order a metal gate work function layer, an oxygen absorption element barrier layer, a metal gate oxygen absorbing layer, a metal gate barrier layer and a polysilicon layer.

2. The gate structure according to claim 1, wherein the thickness of the interface layer thin film is 0-0.5 nm.

3. The gate structure according to claim 1, wherein the thickness of the high k gate dielectric layer is 1-3 nm.

4. The gate structure according to claim 1, wherein the thickness of the metal gate work function layer is 5-30 nm.

5. The gate structure according to claim 1, wherein the thickness of the oxygen absorption element barrier layer is 2-15 nm.

6. The gate structure according to claim 1, wherein the element/elements contained within the metal gate oxygen absorbing layer is/are capable of absorbing oxygen from the interface layer thin film during a thermal processing.

7. The gate structure according to claim 1, wherein the thickness of the metal gate oxygen absorbing layer is 1-10 nm.

8. The gate structure according to claim 1, wherein the thickness of the metal gate barrier layer is 2-15 nm.

9. The gate structure according to claim 1, wherein the thickness of the polysilicon layer is 30-70 nm.

10. A MOS device, comprising the gate structure of any one of claims 1 to 9.

11. A method for forming a gate structure of a MOS device, comprising following steps:
providing a substrate;
forming an interface layer thin film on the substrate;
forming a high k gate dielectric layer on the interface layer thin film;
forming a metal gate work function layer on the high k gate dielectric layer;
forming an oxygen absorption element barrier layer on the metal gate work function layer;
forming a metal gate oxygen absorbing layer on the oxygen absorption element barrier layer;
forming a metal gate barrier layer on the metal gate oxygen absorbing layer;
forming a polysilicon layer on the metal gate barrier layer;
forming a complete gate structure by a rapid thermal annealing process.

12. The method according to claim 11, wherein the thickness of the interface layer thin film is 0.2-0.8 nm.

13. The method according to claim 11, wherein the thickness of the high k gate dielectric layer is 1-3 nm.

14. The method according to claim 11, wherein the thickness of the metal gate work function layer is 5-30 nm.

15. The method according to claim 11, wherein the thickness of the oxygen absorption element barrier layer is 2-15 nm.

16. The method according to claim 11, wherein the element/elements contained within the metal gate oxygen absorbing layer is/are capable of absorbing oxygen from the interface layer thin film during a thermal processing.

17. The method according to claim 16 , wherein the thickness of the metal gate oxygen absorbing layer is 1-10 nm.

18. The method according to claim 11, wherein the thickness of the metal gate barrier layer is 2-15 nm.

19. (canceled)

20. The method according to claim 11, wherein a thermal annealing process is performed at the temperature of 300-1000° C. for about 5 to 300 seconds.

21. The method according to claim 11, wherein the thickness of the interface layer thin film in a complete gate structure is 0-0.5 nm.
